(19) United States
(12) Patent Application Publication
(10) Pub. No.: US 2025/0318110 A1
(43) Pub. Date: Oct. 9, 2025

(54) SEMICONDUCTOR DEVICES

(71) Applicant: SAMSUNG ELECTRONICS CO., LTD., Suwon-si (KR)

(72) Inventors: Hyojung NOH, Suwon-si (KR); Sungnam LYU, Suwon-si (KR); Nayoung LEE, Suwon-si (KR); Eulji JEONG, Suwon-si (KR); Eunmi KIM, Suwon-si (KR); Seohyeong JANG, Suwon-si (KR)

(73) Assignee: SAMSUNG ELECTRONICS CO., LTD., Suwon-si (KR)

(21) Appl. No.: 18/975,680

(22) Filed: Dec. 10, 2024

(30) Foreign Application Priority Data
Apr. 9, 2024 (KR) 10-2024-0048098
Jul. 23, 2024 (KR) 10-2024-0096817

(51) Int. Cl. H10B 12/00; H10D 64/66

(52) U.S. Cl. CPC H10B 12/482; H10B 12/315; H10D 64/665

(57) ABSTRACT

A semiconductor device includes a bit line extending in a first direction, a channel on the bit line, the channel extending in a vertical direction substantially perpendicular to an upper surface of the bit line, a gate insulation pattern, a liner, a gate electrode, a capping pattern and a division pattern sequentially stacked on the channel in the first direction, and a capacitor on and electrically connected to the channel, wherein a first material in the liner has a work function lower than a work function of a second material in the gate electrode.

### CROSS-REFERENCE TO RELATED APPLICATION

This application is based on and claims priority under 35 U.S.C. § 119 to Korean Patent Application No. 10-2024-0048098 filed on Apr. 9, 2024 and Korean Patent Application No. 10-2024-0096817 filed on Jul. 23, 2024 in the Korean Intellectual Property Office, the disclosure of which is hereby incorporated by reference in its entirety.

### BACKGROUND

The disclosure relates to a semiconductor device, and more particularly, to a memory device including a vertical channel.

In semiconductor technology, in order to improve an integration degree of a semiconductor device, a memory device including a vertical channel transistor has been developed. Recently, in the memory device including a vertical channel transistor, word lines include a metal having a low resistance. However, the low-resistance metal has a high work function and a low thermal stability, which may deteriorate the overall performance of the semiconductor device.

### SUMMARY

According to an aspect of the disclosure, there is provided a semiconductor device including: a bit line extending in a first direction; a channel on the bit line, the channel extending in a vertical direction substantially perpendicular to an upper surface of the bit line; a gate insulation pattern, a liner, a gate electrode, a capping pattern and a division pattern provided on the channel in the first direction; and a capacitor on the channel; wherein the liner comprises a first material having a first work function and the gate electrode comprises a second material having a second work function, the first work function being lower than the second work function.

According to another aspect of the disclosure, there is provided a semiconductor device including: a bit line extending in a first direction; a plurality of channels on the bit line, the plurality of channels spaced apart from each other in the first direction and each of the plurality of channels extending in a vertical direction substantially perpendicular to an upper surface of the bit line; a division pattern between two adjacent channels, among the plurality of channels in the first direction, the division pattern extending in the vertical direction; a capping pattern on a first sidewall and a second sidewall of the division pattern; a gate electrode and a liner sequentially provided on a sidewall of the capping pattern; a gate insulation pattern on a sidewall of the liner, the gate insulation pattern contacting each of the plurality of channels; and a capacitor on each of the plurality of channels, wherein the capping pattern comprises a first material having a first work function and the gate electrode comprises a second material having a second work function, the first work function being lower than the second work function.

According to another aspect of the disclosure, there is provided a semiconductor device including: a plurality of bit lines each extending in a first direction, the plurality of bit lines being spaced apart from each other in a second direction crossing the first direction; a plurality of channels on the plurality of bit lines, the plurality of channels spaced apart from each other in the first direction and each of the plurality of channels extending in a vertical direction substantially perpendicular to an upper surface of the plurality of bit lines; a gate insulation pattern, a liner, a gate electrode, a capping pattern, and a division pattern sequentially provided on a sidewall of each of the plurality of channels in the first direction; and a plurality of capacitors on the plurality of channels, respectively, wherein the liner comprises a first material having a first work function and the gate electrode comprises a second material having a second work function, the first work function being lower than the second work function, and wherein the capping pattern comprises silicon nitride or the first material.

According to one or more aspects of the disclosure, a semiconductor device may include a division pattern, and a capping pattern, a gate electrode, a liner and a gate insulation pattern sequentially stacked on the division pattern. The liner contacting the gate electrode may include a material having a work function lower than a work function of a material included in the gate electrode. Thus, a threshold voltage and a flat band voltage of a transistor including a gate structure may be adjusted through the liner.

Additionally, the capping pattern may be provided between the division pattern and the gate electrode. Thus, the capping pattern may prevent the oxidation of the gate electrode by silicon oxide or air included in the division pattern, or the nitridation of the gate electrode by silicon nitride included in the division pattern.

### BRIEF DESCRIPTION OF DRAWINGS

The accompanying drawings herein are incorporated into and form part of the specification, illustrate embodiments consistent with the disclosure, which are used in conjunction with the specification to explain the principles of the disclosure and do not constitute an undue limitation of the disclosure.

FIG. 1 is a plan view illustrating a semiconductor device in accordance with one or more example embodiments.

FIG. 2 is a cross-sectional view taken along line A-A′ of FIG. 1 according to one or more embodiments.

FIGS. 3 to 13 are plan views and cross-sectional views illustrating a method of manufacturing a semiconductor device in accordance with one or more example embodiments.

FIG. 14 is a cross-sectional view illustrating a semiconductor device in accordance with one or more example embodiments.

FIGS. 15 to 19 are a plan view and cross-sectional views illustrating a semiconductor device in accordance with one or more example embodiments.

### DETAILED DESCRIPTION

To promote an understanding of the principles of the disclosure, reference will now be made to the various embodiments and specific language will be used to describe the same. The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. Also, the various embodiments described herein are not necessarily mutually exclusive, as some embodiments can be combined with one or more other embodiments to form new embodiments. The term “or” as used herein, refers to a non-exclusive or, unless otherwise indicated. The examples used herein are intended merely to facilitate an understanding of ways in which the embodiments herein can be practiced and to further enable those skilled in the art to practice the embodiments herein. Accordingly, the examples should not be construed as limiting the scope of the embodiments herein.

Reference throughout this specification to “an aspect”, “another aspect” or similar language means that a particular feature, structure, or characteristic described in connection with the embodiment is included in at least one embodiment of the disclosure. Thus, appearances of the phrase “in an embodiment”, “in another embodiment” and similar language throughout this specification may, but do not necessarily, all refer to the same embodiment.

The terms “comprises”, “comprising”, “has,” “have,” or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components.

The above and other aspects and features of a semiconductor device and a method of forming the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of disclosure.

Hereinafter, two directions that are substantially perpendicular to each other among horizontal directions, which are substantially parallel to an upper surface of a substrate, may be referred to as first and second directions D1 and D2, respectively, and a vertical direction substantially perpendicular to the upper surface of the substrate may be referred to as a third direction D3. In example embodiments, the first and second directions D1 and D2 may be orthogonal to each other.

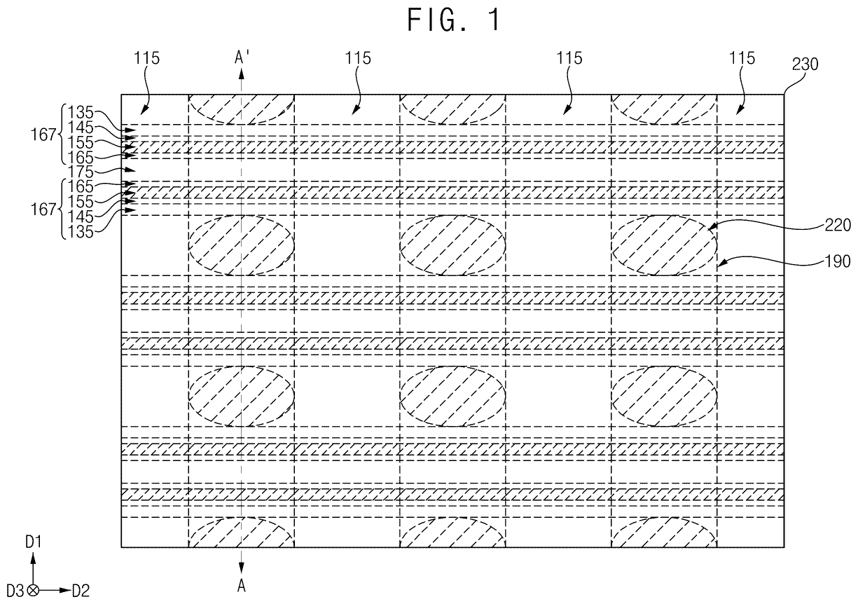

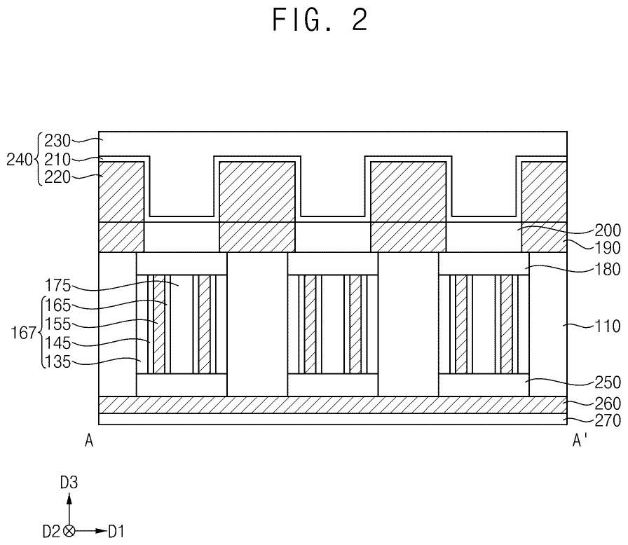

FIG. 1 is a plan view illustrating a semiconductor device in accordance with one or more example embodiments and FIG. 2 is a cross-sectional view taken along line A-A′ of FIG. 1 in accordance with one or more embodiments.

Referring to FIGS. 1 and 2, the semiconductor device may include a bit line 260, a mold 115, a division pattern 175, a gate structure 167, a channel 110, a landing pad 190 and a capacitor 240.

Referring to FIGS. 2, 4, and 13, the semiconductor device may further include a first insulation pattern 180, a second insulation pattern 250, a first insulating interlayer 105, a second insulating interlayer 200, a third insulating interlayer 265 and a fourth insulating interlayer 270.

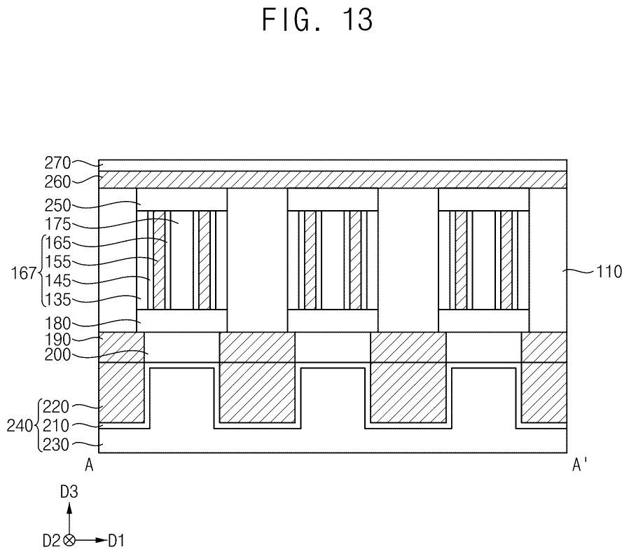

For example, the bit line 260 may extend in the first direction D1 on the fourth insulating interlayer 270 and a plurality of bit lines 260 may be spaced apart from each other in the second direction D2. Referring to FIG. 13, the third insulating interlayer 265 may extend in the first direction D1 between the bit lines 260 neighboring in the second direction D2 on the fourth insulating interlayer 270.

In example embodiments, the bit line 260 may include a conductive material. The conductive material may include, but is not limited to, a metal, a metal nitride, or a metal silicide. Each of the third and fourth insulating interlayers 265 and 270 may include an oxide. The oxide may include, but is not limited to, silicon oxide.

The second insulation pattern 250 may extend in the second direction D2 on the bit line 260 and the third insulating interlayer 265, and a plurality of second insulation patterns 250 may be spaced apart from each other in the first direction D1. In example embodiments, the second insulation pattern 250 may include an oxide. The oxide may include, but is not limited to, silicon oxide.

The division pattern 175 may be provided on a central portion of the second insulation pattern 250 and connected thereto, and may extend in the second direction D2. In some example embodiments, the division pattern 175 may be referred to as separation pattern. For example, the division pattern 175 (or the separation pattern) may be provided between adjacent (or neighboring) word lines. In example embodiments, the division pattern 175 may include an insulating material. The insulating material may include, but is not limited to, silicon oxide or silicon nitride, and in some example embodiments, the division pattern 175 may include a void in the division pattern, which may include air.

The gate structure 167 may be provided on each of opposite sidewalls of the division pattern 175 on the second insulation pattern 250, and may include a capping pattern 165, a gate electrode 155, a liner 145 and a gate insulation pattern 135 sequentially stacked in the first direction D1 on the division pattern 175.

Thus, an inner sidewall of the capping pattern 165 in the first direction D1 may contact a sidewall of the division pattern 175 in the first direction D1, an outer sidewall of the capping pattern 165 in the first direction D1 may contact an inner sidewall of the gate electrode 155 in the first direction D1. An inner sidewall of the liner 145 in the first direction D1 may contact an outer sidewall of the gate electrode 155 in the first direction D1, and an outer sidewall of the liner 145 in the first direction D1 may contact an inner sidewall of the gate insulation pattern 135 in the first direction D1.

In example embodiments, the gate structure 167 may extend in the second direction D2, and a sidewall of the gate structure 167 in the first direction D1, that is, an outer sidewall of the gate insulation pattern 135 in the first direction D1 may be aligned in the third direction D3 with a sidewall of the second insulation pattern 250 in the first direction D1.

In example embodiments, the gate electrode 155 may include a metal, a metal silicon or a metal silicide. For example, the metal may include, but is not limited to, molybdenum (Mo), ruthenium (Ru), tungsten (W), molybdenum (Mo), ruthenium (Ru), or tungsten (W). The metal silicon may include, but is not limited to, molybdenum silicon (MoSi), ruthenium silicon (RuSi), or tungsten silicon (WSi). The metal silicide may include, but is not limited to, molybdenum silicide, ruthenium silicide, or tungsten silicide. The liner 145 may include, but is not limited to, lanthanum oxide (LaO), lanthanum nitride (LaN), scandium oxide (ScO), aluminum oxide (AlO), magnesium oxide (MgO), hafnium oxide (HfO2), ytterbium oxide (Y2O3), tantalum (Ta), tantalum nitride (TaN), titanium silicon nitride (TiSiN), titanium aluminum nitride (TiAlN), aluminum nitride (AlN), titanium aluminum nitride (TiAlC) or a compound of one of the above-mentioned materials and the metal, the metal silicon or the metal silicide.

The gate insulation pattern 135 may include an oxide. The oxide may include, but is not limited to, silicon oxide or aluminum oxide. The capping pattern 165 may include, but is not limited to, silicon nitride, lanthanum oxide (LaO), lanthanum nitride (LaN), scandium oxide (ScO), aluminum oxide (AlO), magnesium oxide (MgO), hafnium oxide (HfO2), ytterbium oxide (Y2O3), tantalum (Ta), tantalum nitride (TaN), titanium silicon nitride (TiSiN), titanium aluminum nitride (TiAlN), aluminum nitride (AlN), titanium aluminum nitride (TiAlC) or a compound of the above-mentioned materials and the metal, the metal silicon or the metal silicide.

In example embodiments, a material included in the liner 145 may have a work function lower than a work function of a material included in the gate electrode 155. In an example embodiment, a material included in the capping pattern 165 may have a work function lower than the work function of the material included in the gate electrode 155.

The first insulation pattern 180 may be provided on the gate structure 167 and the division pattern 175, may extend in the second direction D2. A plurality of first insulation patterns 180 may be spaced apart from each other in the first direction D1. In example embodiments, a lower surface of the first insulation pattern 180 may contact upper surfaces of the division pattern 175, the capping pattern 165, the gate electrode 155, the liner 145 and the gate insulation pattern 135, and a sidewall of the first insulation pattern 180 in the first direction D1 may be aligned in the third direction D3 with a sidewall in the first direction D1 of the gate structure 167.

The first insulation pattern 180 may include an oxide. For example, the oxide may include, but is not limited to, silicon oxide.

The mold 115 may be provided on the third insulating interlayer 265, and may contact an upper surface of the third insulating interlayer 265. The mold 115 may contact a sidewall in the first direction D1 of each of the gate structures 167 neighboring in the first direction D1. The mold 115 may also contact sidewalls in the first direction D1 of the first and second insulation patterns 180 and 250, which are provided on and beneath the gate structures 167, respectively.

In example embodiments, the mold 115 may be provided on the third insulating interlayer 265, and a plurality of molds 115 may be spaced apart from each other in the first direction D1 by the gate structure 167, the division pattern 175 and the first and second insulation patterns 180 and 250. The mold 115 may be provided between channels 110 neighboring in the second direction D2 and may contact sidewalls of the channels 110 in the second direction D2.

The mold 115 may include an insulating material. For example, the insulating material may include, but is not limited to, silicon nitride.

The channel 110 may contact an upper surface of the bit line 260 and the sidewall of each of the gate structures 167 neighboring in the first direction D1. The channel 110 may also contact the sidewalls in the first direction D1 of the first and second insulation patterns 180 and 250, which are provided on and beneath the gate structures 167, respectively.

In example embodiments, an upper surface of the channel 110 may be substantially coplanar with the upper surface of the first insulation pattern 180, and a lower surface of the channel 110 may be substantially coplanar with a lower surface of the second insulation pattern 250.

In example embodiments, the channel 110 may be provided on each of the bit lines 260, and a plurality of channels 110 may be spaced apart from each other in the first direction D1 by the gate structure 167, the division pattern 175 and the first and second insulation patterns 180 and 250. The plurality of channels 110 and the plurality of molds 115 may be alternately and repeatedly provided in the second direction D2.

In example embodiments, the channel 110 may include a semiconductor material. For example, the semiconductor material may include, but is not limited to, silicon (Si), germanium (Ge), silicon-germanium (Si—Ge), etc. However, the disclosure is not limited thereto, and as such, according to some example embodiments, the channel 110 may be include an oxide semiconductor material. The oxide semiconductor material may include, but is not limited to, zinc tin oxide (ZTO), indium zinc oxide (IZO), zinc oxide (ZnOx), indium gallium zinc oxide (IGZO), indium gallium silicon oxide (IGSO), indium oxide (InOx, In₂O₃), SnO₂ (tin oxide), titanium oxide (TiOx), zinc oxide nitride (ZnxOyNz), magnesium zinc oxide (MgxZnyOz), indium zinc oxide (InxZnyOa), indium gallium zinc oxide (InxGayZnzOa), zirconium indium zinc oxide (ZrxInyZnzOa), hafnium indium zinc oxide (HfxInyZnzOa), tin indium zinc oxide (SnxInyZnzOa), aluminum tin indium zinc oxide (AlxSnyInzZnaOd), silicon indiumzinc oxide (SixInyZnzOa), zinc tin oxide (ZnxSnyOz), aluminum zinc tin oxide (AlxZnySnzOa), gallium zinc tin oxide (GaxZnySnzOa), zirconium zinc tin oxide (ZrxZnySnzOa) and indium gallium silicon oxide (InGaSiO).

The second insulating interlayer 200 may be provided on the mold 115, the channel 110 and the first insulation pattern 180. The second insulating interlayer 200 may include an insulating material. The insulating material may include, but is not limited to, silicon oxide or silicon nitride.

The landing pad 190 may be provided on the channel 110. In example embodiments, the landing pad 190 may extend through the second insulating interlayer 200, and may contact the upper surface of the channel 110. The landing pad may further contact upper surfaces of portions of the mold 115 and the first insulation pattern 180 adjacent to the channel 110. However, the landing pad 190 may not contact an upper surface of the gate electrode 155 and may be spaced apart from the gate electrode 155 by the first insulation pattern 180. FIG. 2 shows that a lower surface of the landing pad 190 is wider than the upper surface of the corresponding channel 110, however the disclosure is not limited thereto.

In example embodiments, a plurality of landing pads 190 may be spaced apart from each other in the first and second directions D1 and D2, and may be arranged in a lattice pattern or a honeycomb pattern in a plan view. FIG. 1 shows that the landing pad 190 has a rectangular shape in a plan view. However the disclosure is not limited thereto, and as such, according to another embodiment, the landing pad 190 may have other various shapes. For example, a shape of the landing pad 190 may include, but is not limited to, a circular shape, an oval shape, a shape of a rectangle with rounded corners, etc.

The landing pad 190 may include a conductive material. The conductive material may include, but is not limited to, a metal, a metal nitride, a metal silicide, etc.

The capacitor 240 may include first and second capacitor electrodes 220 and 230 and a dielectric layer 210 between the first and second capacitor electrodes 220 and 230. In example embodiments, the first capacitor electrode 220 may be provided on the landing pad 190, the dielectric layer 210 may be provided on an upper surface and a sidewall of the first capacitor electrode 220 and an upper surface of the second insulating interlayer 200, and the second capacitor electrode 230 may be provided on the dielectric layer 210.

As the plurality of landing pads 190 is space apart from each other in the first and second directions D1 and D2, a plurality of first capacitor electrodes 220 may also be spaced apart from each other in the first and second directions D1 and D2.

In example embodiments, a shape of the first capacitor electrode 220 may include, but is not limited to, a circle, an ellipse, a polygon, a polygon with rounded corners, etc., in a plan view. The first capacitor electrode 220 may be arranged in a lattice pattern or a honeycomb pattern in a plan view.

The first capacitor electrode 220 may include, but is not limited to, a metal, a metal nitride, a metal silicide, etc. The dielectric layer 210 may include, but is not limited to, a metal oxide. The second capacitor electrode 230 may include, but is not limited to, a metal, a metal nitride, a metal silicide, a silicon-germanium doped with impurities, etc.

In the semiconductor device, current may flow in the third direction D3, that is, in the vertical direction, within the channel 110 between the bit line 260 and the landing pad 190, and thus the semiconductor device may include a vertical channel transistor (VCT), which may have a vertical channel.

As illustrated above, the gate structure 167 on each of the opposite sidewalls of the division pattern 175 may include the capping pattern 165, the gate electrode 155, the liner 145 and the gate insulation pattern 135 sequentially stacked in the first direction D1 on the division pattern 175. The liner 145 contacting the gate electrode 155 may include the material having the work function lower than the work function of the material included in the gate electrode 155, so that an overall work function of the gate electrode 155 and the liner 145 may be lower than the work function of the gate electrode 155. Thus, a threshold voltage and a flatband voltage of the transistor including the gate structure 167 may be adjusted through the liner 145.

The capping pattern 165 may be interposed between the division pattern 175 and the gate electrode 155. Thus, the oxidation of the gate electrode 155 by silicon oxide or air included in the division pattern 175 or the nitridation of the gate electrode 155 by silicon nitride included in the division pattern 175 may be prevented.

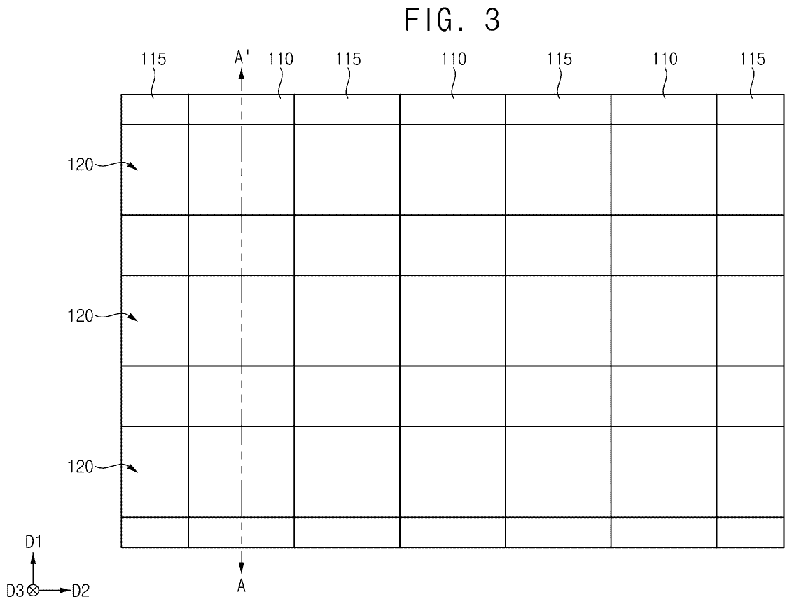

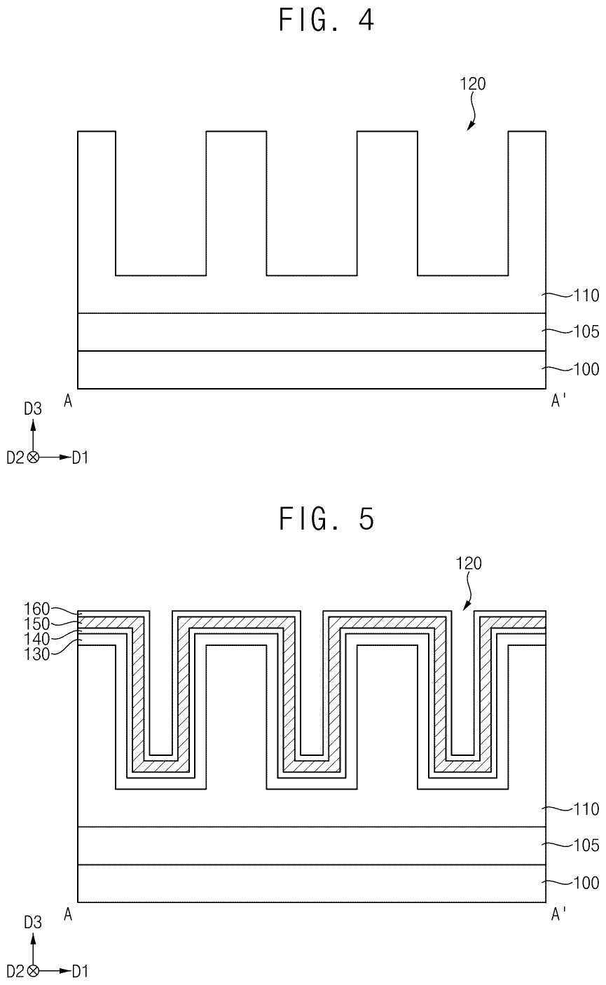

FIGS. 3 to 13 are plan views and cross-sectional views illustrating a method of manufacturing a semiconductor device in accordance with example embodiments. For example, FIGS. 3, 7 and 12 are the plan views, and FIGS. 4-6, 8-11 and 13 are cross-sectional views taken along lines A-A′ of corresponding plan views, respectively.

Referring to FIGS. 3 and 4, a first insulating interlayer 105 and a channel layer may be sequentially formed on a substrate 100, and an etching process may be performed on the channel layer to form a first opening exposing an upper surface of the first insulating interlayer 105.

In example embodiments, the first opening may extend in the first direction D1 and a plurality of first openings may be spaced apart from each other in the second direction D2.

A deposition process may be performed to form a mold layer on the first insulating interlayer 105 and the channel layer to fill the first opening, and a planarization process may be performed on the mold layer until an upper surface of the channel layer is exposed, so that the mold layer may be formed on the first insulating interlayer 105 to extend in the first direction D1. The planarization process may include, but is not limited to, a chemical mechanical polishing (CMP) process and/or an etch back process.

In example embodiments, a plurality of mold layers may be spaced apart from each other in the second direction D2, and thus, the mold layer and the channel layer may be alternately and repeatedly formed in the second direction D2.

An etching process may be performed on upper portions of the mold layer and the channel layer to form a first trench 120. In example embodiments, the first trench 120 may extend in the second direction D2. For example, a plurality of first trenches 120 may be spaced apart from each other in the first direction D1.

As the first trench 120 is formed, the mold layer and the channel layer may be transformed into a mold 115 and a channel 110, respectively. Hereinafter, in each of the channel 110 and the mold 115, a portion extending in the first direction D1 below the first trench 120 may be referred to as a lower portion, and a portion between the first trenches 120 provided in the first direction D1 may be referred to as an upper portion.

Referring to FIG. 5, a gate insulation layer 130, a liner layer 140, a gate electrode layer 150, and a capping layer 160 may be provided on the channel 110 and the mold 115. For example, the gate insulation layer 130, the liner layer 140, the gate electrode layer 150, and the capping layer 160 may be sequentially stacked on the channel 110 and the mold 115.

In example embodiments, each of the gate insulation layer 130, the liner layer 140, the gate electrode layer 150 and the capping layer 160 may be formed by a deposition process. The deposition process may include, but is not limited to, a chemical vapor deposition (CVD) process, an atomic layer deposition (ALD) process, etc. In an example embodiment, the deposition processes may be performed in-situ.

The liner layer 140 may serve as a seed layer for the deposition process of the gate electrode layer 150 and may prevent a metal in the gate electrode layer from diffusing into the gate insulation layer 130.

The first trench 120 may not be completely filled by the gate insulation layer 130, the liner layer 140, the gate electrode layer 150 and the capping layer 160, and may remain partially unfilled. For example, an opening is present in the channel 110 after the gate insulation layer 130, the liner layer 140, the gate electrode layer 150 and the capping layer 160 are provided in the trench 120. As such, a width of the first trench 120 in the first direction D1 may be decreased when compared to a prior width of the first trench 120 before being filled with the gate insulation layer 130, the liner layer 140, the gate electrode layer 150 and the capping layer 160.

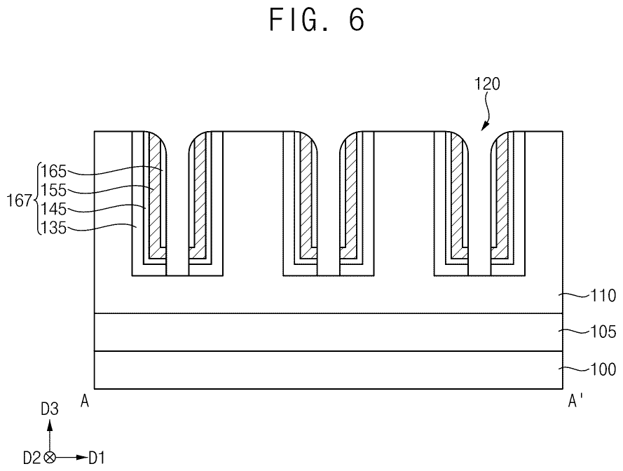

Referring to FIG. 6, an anisotropic etching process may be performed on the gate insulation layer 130, the liner layer 140, the gate electrode layer 150 and the capping layer 160. For example, the anisotropic etching process may transform the gate insulation layer 130, the liner layer 140, the gate electrode layer 150 and the capping layer 160 may transformed into a gate insulation pattern 135, a liner 145, a gate electrode 155 and a capping pattern 165, respectively.

In example embodiments, each of the gate insulation pattern 135, the liner 145, the gate electrode 155 and the capping pattern 165 may be formed on each of opposite sidewalls in the first direction D1 of each of the channel 110 and the mold 115, and may extend in the second direction D2. As the anisotropic etching process is performed, a central bottom of the first trench 120 may be exposed.

The gate insulation pattern 135, the liner 145, the gate electrode 155 and the capping pattern 165 may collectively form a gate structure 167.

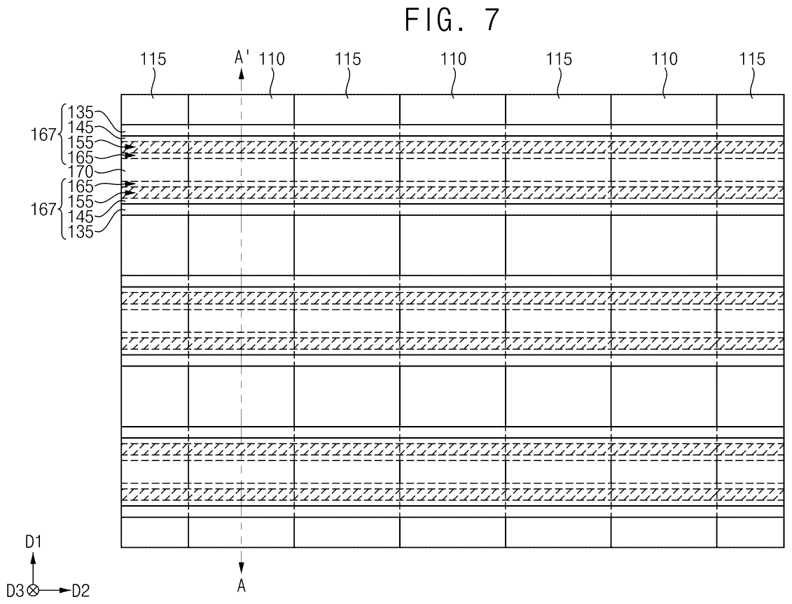

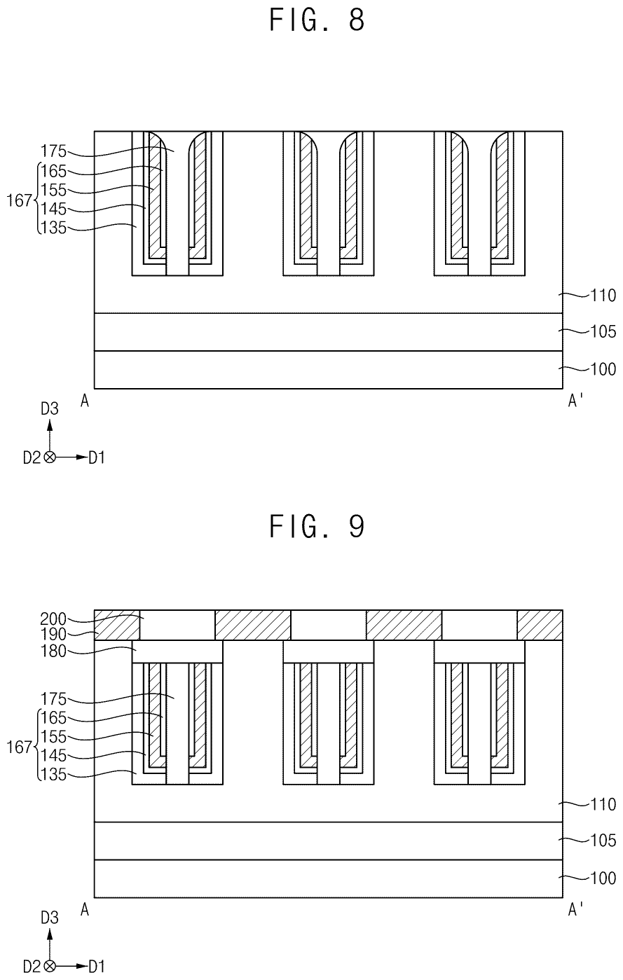

Referring to FIGS. 7 and 8, a division layer may be formed on the channel 110 and the mold 115 to fill the first trench 120. In some example embodiments, a planarization process may be performed on the division layer to form the division pattern 175.

The planarization process may include, but is not limited to, a chemical mechanical polishing (CMP) process and/or an etch back process.

In example embodiments, the division pattern 175 may contact a sidewall of the capping pattern 165 in the first direction D1 and may extend in the second direction D2.

Referring to FIG. 9, upper portions of the gate structure 167 and the division pattern 175 may be removed to form a second trench, and a first insulation pattern 180 may be formed to fill the second trench. However, the disclosure is not limited thereto, and as such, according to another embodiment, the first insulation pattern 180 may be formed on the gate structure 167 and the division pattern 175 in another manner.

In some example embodiment, the first insulation pattern 180 may be formed by providing a first insulation layer on the gate structure 167, the division pattern 175, the channel 110 and the mold 115, and performing a planarization process on the first insulation layer. For example, the method may include providing the first insulation layer in the second trench formed on the gate structure 167, the division pattern 175, the channel 110 and the mold 115. In example embodiments, the first insulation pattern 180 may extend in the second direction D2, and a plurality of first insulation patterns 180 may be spaced apart from each other in the first direction D1. In some example embodiments, a first sidewall of the first insulation pattern 180 may contact a first sidewall of the channel 110 and a first sidewall of the mold 115, and a second sidewall of the first insulation pattern 180 may contact a second sidewall of the channel 110 and a second sidewall of the mold 115.

A second insulating interlayer 200 may be formed on the channel 110, the mold 115 and the first insulation pattern 180, and a landing pad 190 may be formed through the second insulating interlayer 200 to contact an upper surface of the channel 110.

In example embodiments, a plurality of landing pads 190 may be spaced apart from each other in the first and second directions D1 and D2, and each of the landing pads 190 may contact an upper surface of an upper portion of a corresponding one of the channels 110.

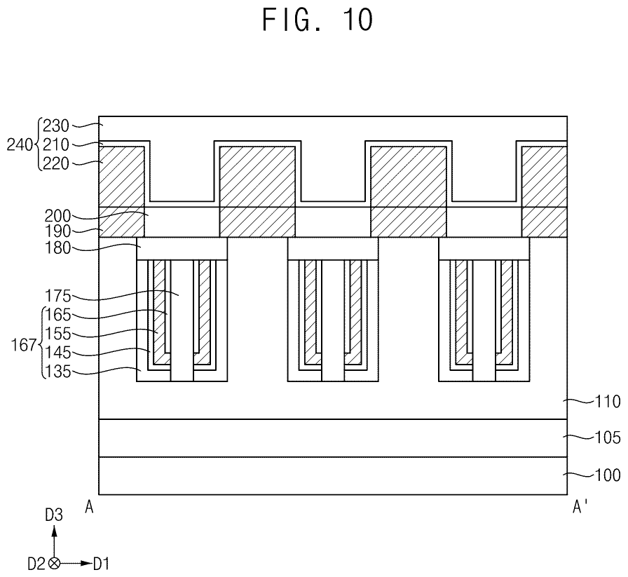

Referring to FIG. 10, a first capacitor electrode 220 contacting an upper surface of the landing pad 190 may be formed on the second insulating interlayer 200 and the landing pad 190, a dielectric layer 210 may be formed on the landing pad 190 and the second insulating interlayer 200, and a second capacitor electrode 230 may be formed on the dielectric layer 210.

In example embodiments, a plurality of first capacitor electrodes 220 may be spaced apart from each other in the first and second directions D1 and D2 and each of the first capacitor electrodes 220 may contact an upper surface of a corresponding one of the landing pads 190.

The first capacitor electrode 220, the dielectric layer 210 and the second capacitor electrode 230 may collectively form a capacitor 240.

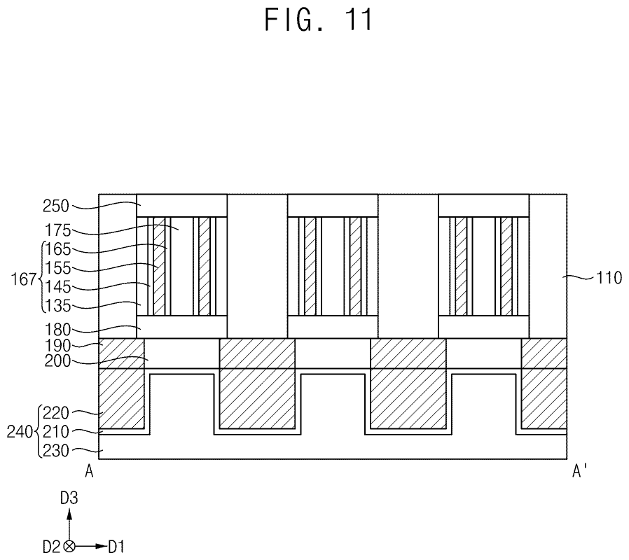

Referring to FIG. 11, the substrate 100 may be flipped so that various structures on the substrate 100 may flipped upside down, and hereinafter are described based on the changed direction. That is, for example, the upper portion and the lower portion of each of the channel 110 and the mold 115 may be referred to as a lower portion and an upper portion, respectively, of each of the channel 110 and the mold 115.

In example embodiments, a grinding process may be performed on the substrate 100, the first insulating interlayer 105, and the upper portions of the channel 110 and the mold 115 to expose upper surfaces of the division pattern 175 and the gate insulation pattern, and thus only the lower portion of each of the channel 110 and the mold 115 may remain. As a result, the channel 110 may be divided into a plurality of the channels 110 spaced apart from each other in the first direction D1, and the mold 115 may be divided into a plurality of molds 115 spaced apart from each other in the first direction D1. In example embodiments, a plurality of channels 110 may be spaced apart from each other in the first and second directions D1 and D2, and a plurality of molds 115 may be spaced apart from each other in the first and second directions D1 and D2.

An etching process may be performed to remove an upper portion of each of the gate insulation pattern 135, the liner 145, the gate electrode 155 and the division pattern 175 to form a third trench, a second insulation layer may be formed on the channel 110, mold 115, gate structure 167 and division pattern 175 to fill the third trench, and a planarization process may be performed on the second insulation layer until upper surfaces of the channel 110 and mold 115 are exposed, to form a second insulation pattern 250.

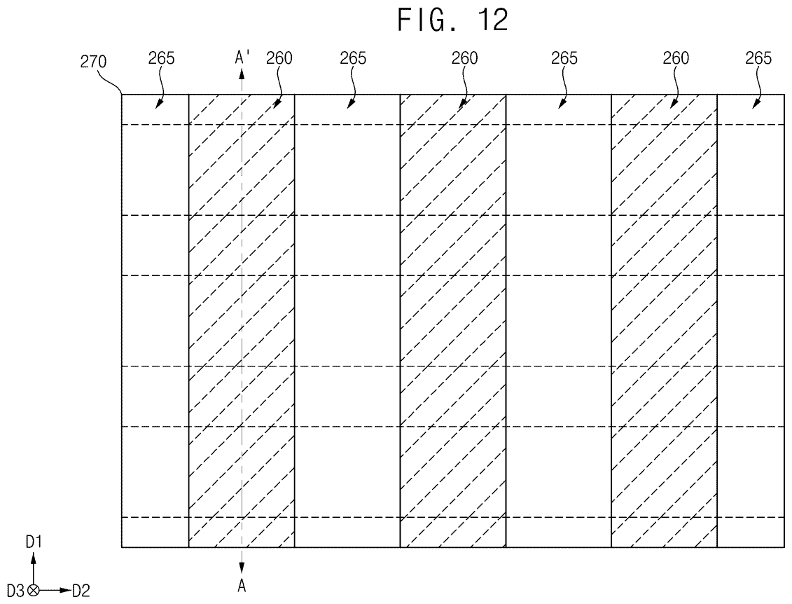

Referring to FIGS. 12 and 13, a third insulating interlayer 265 may be formed on the channel 110, the mold 115 and the second insulation pattern 250, the third insulating interlayer 265 may partially be removed to form a conductive layer contacting the upper surface of the channel 110, and a planarization process may be performed on the conductive layer until an upper surface of the third insulating interlayer 265 is exposed to form a bit line 260.

In example embodiments, the bit line 260 may extend in the first direction D1 and a plurality of bit lines 260 may be spaced apart from each other in the second direction D2.

Referring back to FIGS. 1 and 2, a fourth insulating interlayer 270 may be formed on the bit line 260 and the third insulating interlayer 265, and the substrate 100 may be flipped to complete the fabrication of the semiconductor device.

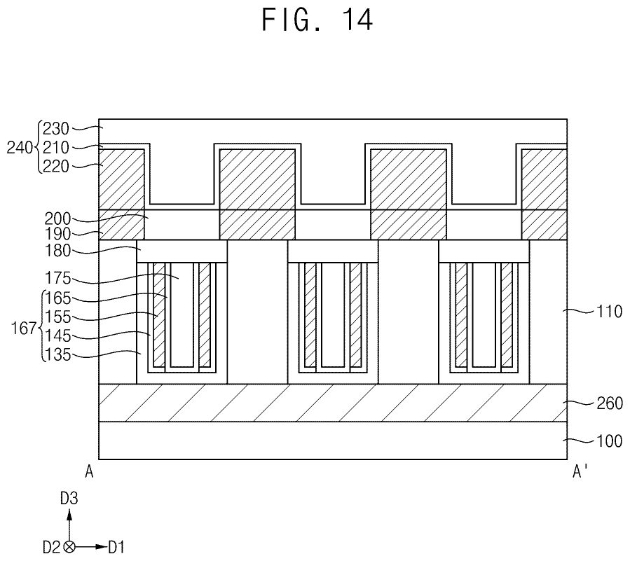

FIG. 14 is a cross-sectional view illustrating a semiconductor device in accordance with example embodiments. This semiconductor device may be substantially the same as or similar to that of FIGS. 1 and 2, except for shapes of the gate structure 167 and the division pattern 175 and not including the second insulation pattern 250, and thus repeated explanations are omitted herein.

Referring to FIG. 14, the capping pattern 165 may be provided on a lower surface of the division pattern 175 and on each of a first sidewall and a second sidewall opposite of the division pattern 175. For example, the capping pattern 165 may cover a lower surface of the division pattern 175 as well as each of the first and second sidewalls of the division pattern 175 that are opposite to each other in the first direction D1. The liner 145 may be provided on a lower surface of the gate electrode 155 and on an outer sidewall of the gate electrode 155. For example, the liner pattern 175 may cover a lower surface of the gate electrode 155 as well as the outer sidewall in the first direction D1 of the gate electrode 155.

Thus, a cross-section in the second direction D2 of the capping pattern 165 may have a cup shape, and the cross-section of the liner 145 in the second direction D2 may have an “L” shape.

The gate insulation pattern 135 may be provided on the bit line 260, and may include a horizontal portion, which may have a lower surface contacting the upper surface of the bit line 260, and a vertical portion on the horizontal portion, which may have an outer sidewall contacting a sidewall of the channel 110. Thus, in example embodiments, a cross-section in the second direction D2 of the gate insulation pattern 135 may have a cup shape.

A central portion in the first direction D1 of an upper surface of the horizontal portion of the gate insulation pattern 135 may contact a lower surface of the capping pattern 165, and each of opposite lateral portions in the first direction D1 of the upper surface of the horizontal portion of the gate insulation pattern 135 may contact a lower surface of the liner 145.

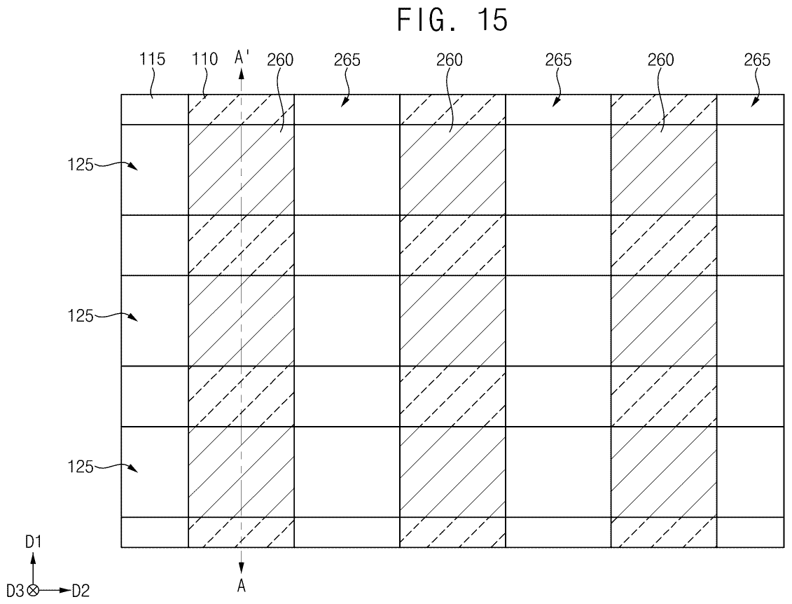

FIGS. 15 to 19 are a plan view and cross-sectional views illustrating a method of manufacturing the semiconductor device in accordance with example embodiments. This method may include processes substantially the same as or similar to those illustrated with reference to FIGS. 3 to 14 and FIGS. 1 and 2, and thus repeated explanations are omitted herein.

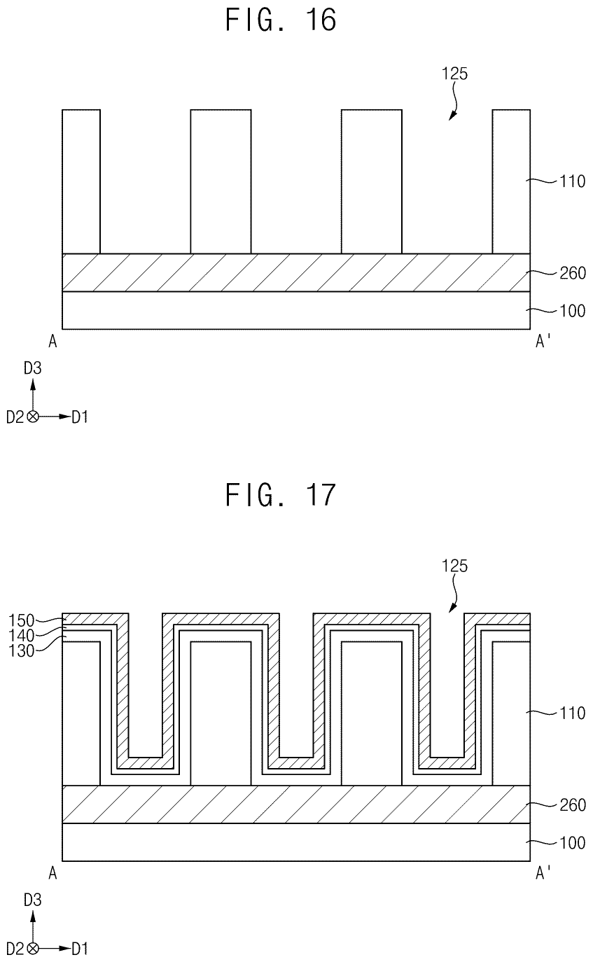

Referring to FIGS. 15 and 16, a bit line layer may be formed on the substrate 100 and patterned to form the bit line 260.

In example embodiments, the bit line 260 may extend in the first direction D1 on the substrate 100 and a plurality of bit lines 260 may be spaced apart from each other in the second direction D2. Thus, a second opening exposing an upper surface of the substrate 100 may be formed between the adjacent (or neighboring) bit lines 260 in the second direction D2.

A preliminary third insulating interlayer may be formed on the bit lines 260 and the substrate 100 to fill the second opening, a planarization process may be performed on an upper portion of the preliminary third insulating interlayer until the upper surfaces of the bit lines 260 are exposed, and thus the third insulating interlayer 265 extending in the first direction D1 may be formed between the adjacent bit lines 260.

The channel 110 and the mold 115 may be formed on the bit line 260 and the third insulating interlayer 265, respectively, and a structure including the channel 110 and the mold 115 may extend in the second direction D2. Additionally, a third opening 125 exposing the upper surfaces of the bit line 260 and the third insulating interlayer 265 may be formed between the adjacent (or neighboring) structures in the first direction D1.

Referring to FIG. 17, the gate insulation layer 130, the liner layer 140 and the gate electrode layer 150 may sequentially be formed on the mold 115, the channel 110, the bit line 260 and the third insulating interlayer 265.

In example embodiments, the gate insulation layer 130 may contact the upper surfaces of the bit line 260 and the third insulating interlayer 265, and each of opposite sidewalls in the first direction D1 and an upper surface of the structure.

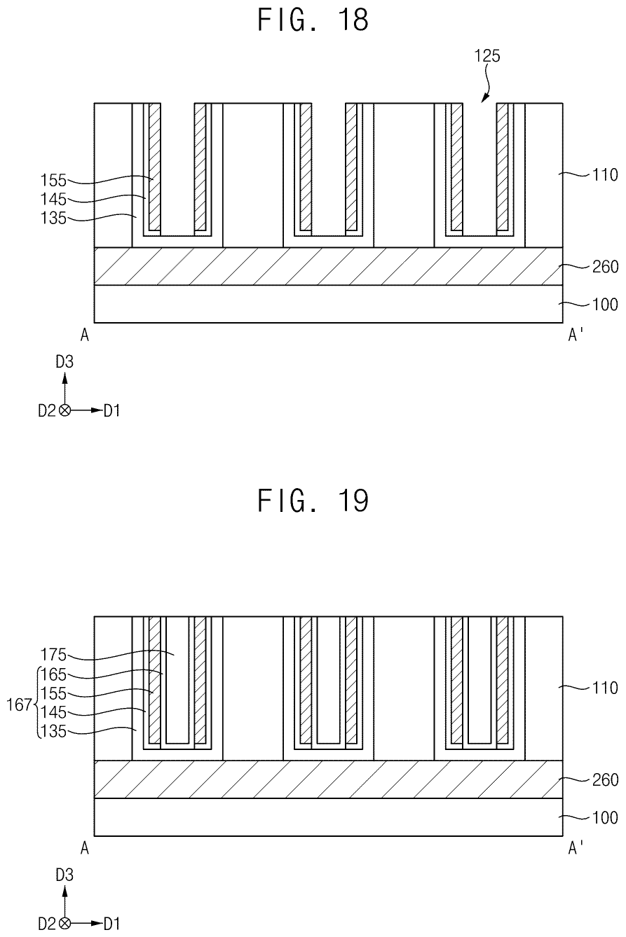

Referring to FIG. 18, an anisotropic etching process may be performed on the gate insulation layer 130, the liner layer 140 and the gate electrode layer 150 to form the gate insulation pattern 135, the liner 145 and the gate electrode 155, respectively, on each of the opposite sidewalls of the structure in the first direction D1.

During the anisotropic etching process, a lower portion of the gate insulation layer 130 may remain, and a central portion of an upper surface of the lower portion of the gate insulation layer 130 may be exposed.

Referring to FIG. 19, the capping layer 160 and the division layer may be formed on the gate insulation pattern 135, the liner 145, the gate electrode 155, the channel 110 and the mold 115 to fill the third opening 125, and a planarization process may be performed on the capping layer 160 and the division layer to form the capping pattern 165 and the division pattern 175, respectively.

Referring back to FIG. 14, processes substantially the same as or similar to those illustrated with reference to FIGS. 9 to 10 may be performed to complete the fabrication of the semiconductor device.

The foregoing is illustrative of example embodiments of the disclosure, and is not to be construed as limiting the disclosure. Although a few example embodiments have been described, those skilled in the art will readily appreciate that many modifications are possible in the example embodiments without materially departing from the novel teachings and advantages of the disclosure. Accordingly, all such modifications are intended to be included within the scope of the disclosure as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a bit line extending in a first direction;
a channel on the bit line, the channel extending in a vertical direction substantially perpendicular to an upper surface of the bit line;
a gate insulation pattern, a liner, a gate electrode, a capping pattern and a division pattern provided on the channel in the first direction; and
a capacitor on the channel;
wherein the liner comprises a first material having a first work function and the gate electrode comprises a second material having a second work function, the first work function being lower than the second work function.

2. The semiconductor device according to claim 1, wherein the second material comprises molybdenum (Mo), ruthenium (Ru), tungsten (W), molybdenum silicon (MoSi), ruthenium silicon (RuSi), tungsten silicon (WSi), molybdenum silicide, ruthenium silicide or tungsten silicide.

3. The semiconductor device according to claim 2, wherein the first material comprises lanthanum oxide (LaO), lanthanum nitride (LaN), scandium oxide (ScO), aluminum oxide (AlO), magnesium oxide (MgO), hafnium oxide (HfO2), ytterbium oxide (Y2O3), and tantalum, (Ta), tantalum nitride (TaN), titanium silicon nitride (TiSiN), titanium aluminum nitride (TiAlN), aluminum nitride (AlN), titanium aluminum nitride (TiAlC), or a compound of one of the above-mentioned materials and the second material.

4. The semiconductor device according to claim 3, wherein the capping pattern comprises silicon nitride or the first material.

5. The semiconductor device according to claim 4, wherein the division pattern comprises silicon oxide, silicon nitride or air.

6. The semiconductor device according to claim 1, wherein the gate insulation pattern comprises silicon oxide or aluminum oxide, and
wherein the channel comprises Indium-Gallium-Zinc Oxide (IGZO) or silicon oxide.

7. The semiconductor device according to claim 1, further comprising a landing pad on the channel and contacting the channel, and
wherein the landing pad contacts the capacitor.

8. The semiconductor device according to claim 1, further comprising an insulation pattern contacting a lower surface of the gate insulation pattern, a lower surface the liner, a lower surface the gate electrode and a lower surface of the capping pattern.

9. The semiconductor device according to claim 1, further comprising an insulation pattern contacting an upper surface of the gate insulation pattern, an upper surface of the liner, an upper surface of the gate electrode and an upper surface of the capping pattern.

10. The semiconductor device according to claim 1, wherein the capping pattern is provided on a sidewall of the division pattern and a lower surface of the division pattern.

11. The semiconductor device according to claim 10, wherein the liner is provided on a sidewall of the gate electrode and a lower surface of the gate electrode,
wherein the liner contacts the capping pattern.

12. The semiconductor device according to claim 10, wherein the liner and the capping pattern contact the gate insulation pattern.

13. A semiconductor device comprising:
a bit line extending in a first direction;
a plurality of channels on the bit line, the plurality of channels spaced apart from each other in the first direction and each of the plurality of channels extending in a vertical direction substantially perpendicular to an upper surface of the bit line;
a division pattern between two adjacent channels, among the plurality of channels in the first direction, the division pattern extending in the vertical direction;
a capping pattern on a first sidewall and a second sidewall of the division pattern;
a gate electrode and a liner sequentially provided on a sidewall of the capping pattern;
a gate insulation pattern on a sidewall of the liner, the gate insulation pattern contacting each of the plurality of channels; and
a capacitor on each of the plurality of channels,
wherein the capping pattern comprises a first material having a first work function and the gate electrode comprises a second material having a second work function, the first work function being lower than the second work function.

14. The semiconductor device according to claim 13, wherein the second material comprises molybdenum (Mo), ruthenium (Ru), tungsten (W), molybdenum silicon (MoSi), ruthenium silicon (RuSi), tungsten silicon (WSi), molybdenum silicide, ruthenium silicide or tungsten silicide, and
wherein the first material comprises lanthanum oxide (LaO), lanthanum nitride (LaN), scandium oxide (ScO), aluminum oxide (AlO), magnesium oxide (MgO), hafnium oxide (HfO), ytterbium oxide (YO), tantalum (Ta), tantalum nitride (TaN), titanium silicon nitride (TiSiN), titanium aluminum nitride (TiAlN), aluminum nitride (AlN), titanium aluminum nitride (TiAlC), or a compound of one of the above-mentioned materials and the second material.

15. The semiconductor device of claim 13, wherein the liner comprises titanium nitride or the first material.

16. The semiconductor device of claim 13, wherein the division pattern comprises silicon oxide, silicon nitride or air.

17. The semiconductor device of claim 13, wherein the capping pattern provided a sidewall of the division pattern and a lower surface of the division pattern.

18. A semiconductor device comprising:
a plurality of bit lines each extending in a first direction, the plurality of bit lines being spaced apart from each other in a second direction crossing the first direction;
a plurality of channels on the plurality of bit lines, the plurality of channels spaced apart from each other in the first direction and each of the plurality of channels extending in a vertical direction substantially perpendicular to an upper surface of the plurality of bit lines;
a gate insulation pattern, a liner, a gate electrode, a capping pattern, and a division pattern sequentially provided on a sidewall of each of the plurality of channels in the first direction; and
a plurality of capacitors on the plurality of channels, respectively,
wherein the liner comprises a first material having a first work function and the gate electrode comprises a second material having a second work function, the first work function being lower than the second work function, and
wherein the capping pattern comprises silicon nitride or the first material.

19. The semiconductor device according to claim 18, wherein the second material comprises molybdenum (Mo), ruthenium (Ru), tungsten (W), molybdenum silicon (MoSi), ruthenium silicon (RuSi), tungsten silicon (WSi), molybdenum silicide, ruthenium silicide or tungsten silicide, and
wherein the first material comprises lanthanum oxide (LaO), lanthanum nitride (LaN), scandium oxide (ScO), aluminum oxide (AlO), magnesium oxide (MgO), hafnium oxide (HfO2), ytterbium oxide (Y2O3), and tantalum, (Ta), tantalum nitride (TaN), titanium silicon nitride (TiSiN), titanium aluminum nitride (TiAlN), aluminum nitride (AlN), titanium aluminum nitride (TiAlC), or a compound of one of the above-mentioned materials and the second material.

20. The semiconductor device according to claim 18, wherein the capping pattern provided on a first sidewall of the division pattern, a second sidewall of the division pattern, and a lower surface of the division pattern.
